(19) United States
(12) Patent Application Publication
(10) Pub. No.: US 2009/0261459 A1
(43) Pub. Date: Oct. 22, 2009

(54) SEMICONDUCTOR DEVICE HAVING A FLOATING BODY WITH INCREASED SIZE AND METHOD FOR MANUFACTURING THE SAME

(76) Inventor: Tae Kyung OH, Jeju-do (KR)

Correspondence Address: LADAS & PARRY LLP, 224 SOUTH MICHIGAN AVENUE, SUITE 1600, CHICAGO, IL, 60604, US

(21) Appl. No.: 12/189,934

(22) Filed: Aug. 12, 2008

(30) Foreign Application Priority Data
Apr. 21, 2008 (KR) 10-2008-0036617

(51) Int. Cl. H01L 23/58; H01L 21/3205

(52) U.S. Cl. 257/632; 438/585; 257/E21.002

(57) ABSTRACT

A semiconductor device with a silicon on insulator substrate having a stacked structure including a silicon substrate, a filled oxide layer, and a silicon layer is provided with a fin pattern formed in the direction of the channel width in a gate forming region of the silicon layer. The fin pattern has a width that is wider at the lower end portion of the fin pattern than the width of the upper end portion. A gate is formed to cover the fin pattern, and junction regions are formed within the silicon layer at both sides of the gate.

### CROSS-REFERENCE TO RELATED APPLICATIONS

The present application claims priority to Korean patent application number 10-2008-0036617 filed on Apr. 21, 2008, which is incorporated herein by reference in its entirety.

### BACKGROUND OF THE INVENTION

The present invention relates generally to a semiconductor device and a method for manufacturing the same, and more particularly, to a semiconductor device capable of improving a punch-though phenomenon and increasing the volume of the body of a transistor and a method for manufacturing the same.

Recent trends in the semiconductor industry have focused on improvements in the level of integration of a semiconductor device as well as increasing the manufacturing yield. One example of a semiconductor device resulting from these recent trends is a semiconductor device having a floating body cell (hereinafter, referred to as FBC) structure. The semiconductor device having the FBC structure does not require a capacitor for storing information, and thus the FBC structure is advantageous when manufacturing highly integrated devices (where space is limited) when compared to conventional dynamic random access memory (DRAM) requiring a capacitor.

The structure and operation of a semiconductor device having the FBC structure is briefly described below.

In a semiconductor device having the FBC structure a body of a transistor (which corresponds to the area between the source area and the drain area) is floated; and more particularly, the semiconductor device having the FBC structure is formed with no capacitor for storing information.

In the semiconductor device having the FBC structure, a voltage is applied to a gate through a word line to turn a transistor on, and thereafter, when a high potential positive voltage is applied to the drain area via a bit line, hot carriers are generated, and electrons and holes are generated by collision ionization caused by the hot carrier. When the electrons are discharged to the drain due to the high voltage applied to the drain, the holes accumulate in the floating body. The threshold voltage Vt of the transistor is lowered by the accumulated holes, and thus much current flows through the transistor when a voltage is applied, the transistor serves as a memory. For example, in the semiconductor device having the FBC structure, a logic “0” state is the state in which a high threshold voltage exists due to no accumulation of the holes, and logic “1” state is the state in which a low threshold voltage exists due to an accumulation of the holes.

This semiconductor device having the FBC structure has a major advantage, in that a DRAM cell is operable without the use of a capacitor. This becomes even more advantageous when considering future micro processes for manufacturing highly integrated semiconductor devices.

Meanwhile, in order to expand the channel area of a semiconductor device, attempts have been made to design semiconductor devices with a three dimensional channel structure One such proposed device is a fin transistor having a channel with a three dimensional structure.

In the fin transistor, a fin pattern is formed by etching an isolation region to expose an active region, and then a gate is formed in order to cover the projected active region, i.e. the fin pattern. This fin transistor has an advantage, in that the short channel effect is restricted and the current driving characteristic through a channel is enhanced as the channel is formed of all of the three exposed surfaces of the active region.

However, in the semiconductor device employing the aforementioned fin pattern and FBC structure, the area of the body is reduced, and thus a difference in threshold voltage between when the holes are stored in the body and when the holes are flowed out from the body is small. Therefore, it is difficult to distinguish a digital data “1” from a digital data “0”.

If the width of the pin pattern is increased in order to increase the area of the body, a punch-through phenomenon is caused in the follow-up process at an upper portion of the fin pattern that is in contact with a contact plug.

### SUMMARY OF THE INVENTION

Embodiments of the present invention are directed to a semiconductor device a floating body with an increased size and a method for manufacturing the same.

Additionally, embodiments of the present invention are directed to a semiconductor device in which no punch-through phenomenon is generated and a method for manufacturing the same.

In one embodiment, a semiconductor device comprises a silicon on insulator (SOI) substrate having a stacked structure of a silicon substrate, a filled oxide layer and a silicon layer, and provided with a fin pattern formed in the direction of the channel width in a gate forming region of the silicon layer, the fin pattern having a width that is wider at a lower end portion than the width of an upper end portion; a gate formed to cover the fin pattern; and a junction region formed within the silicon layer at both sides of the gate.

The fin pattern has a width in the range of 30-40 nm at the upper end portion and a width in the range of 50-70 nm at the lower end portion.

The junction region has a concentration slope in which the concentration becomes lower as it is goes from the surface of the silicon layer to the filled oxide layer.

The semiconductor device may further comprise an interlayer dielectric layer formed over the SOI substrate formed with the gate and the junction region; and a contact plug formed within the interlayer dielectric layer so as to be in contact with the junction region.

The contact plug includes a polysilicon layer having a concentration in the range of 1.0×10²⁰-2.0×10²⁰ ions/cm³.

In another embodiment, a method for manufacturing a semiconductor device comprises forming an active region by etching a silicon layer of a SOI substrate having a stacked structure of a silicon substrate, a filled oxide layer, and the silicon layer; forming a fin pattern having a width that is wider at a lower end portion than the width of an upper end portion by recessing both edge portions of a gate forming region in a direction of a channel width in the active region; forming a gate to cover the fin pattern; and forming a junction region within the active region at both sides of the gate.

The step of forming the fin pattern includes forming a mask pattern for exposing both edge portions of the gate forming region over the active region in the direction of channel width; recessing the exposed portion of the active region using the mask pattern as an etching mask; and removing the mask pattern.

The step of recessing the exposed portion of the active region is carried out so that the exposed portion of the active region is removed at a thickness in the range of 300-500Å.

The fin pattern is formed so as to have a width in the range of 30-40 nm at the upper end portion thereof and a width in the range of 50-70 nm at the lower end portion thereof.

The method may further comprises, after the step of forming the fin pattern and before the step of forming the gate so as to cover the fin pattern, the step of forming a liner insulation layer over the surface of the rest active region except for the fin pattern.

The junction region is formed by ion implanting N type impurities at a dose in the range of 1.0×10¹³ to 1.0×10¹⁴ ions/cm² at an energy in the range of 20 to 50 keV.

The junction region has a concentration slope in which the concentration becomes lower as it is goes from the surface of the silicon layer to the filled oxide layer.

The method may further comprises, forming an interlayer dielectric layer over the SOI substrate formed with the gate and the junction region so as to fill in the space between the gates; forming a contact hole for exposing the junction region by etching the interlayer dielectric layer; and forming a contact plug in contact with the junction region within the interlayer dielectric layer.

The contact plug is formed of a polysilicon layer having a concentration in the range of 1.0×10²⁰-2.0×10²⁰ ions/cm³.

### BRIEF DESCRIPTION OF THE DRAWINGS

FIG. 1 is a plan view showing a semiconductor device in accordance with an embodiment of the present invention.

FIG. 2 is a cross-sectional view taken along line X-X′ of FIG. 1 and showing the semiconductor device in accordance with an embodiment of the present invention.

FIG. 3 is a cross-sectional view taken along line Y-Y′ of FIG. 1 and showing the semiconductor device in accordance with an embodiment of the present invention.

FIGS. 4A through 4H are plan views shown for illustrating the steps in a method for manufacturing the semiconductor device in accordance with an embodiment of the present invention.

FIGS. 5A through 5H are cross-sectional views taken along line X-X′ of FIGS. 4A through 4H respectively, and shown for illustrating the steps in a method for manufacturing the semiconductor device in accordance with an embodiment of the present invention.

FIGS. 6A through 6H are cross-sectional views taken along line Y-Y′ of FIGS. 4A through 4H respectively, and shown for illustrating the steps in a method for manufacturing the semiconductor device in accordance with an embodiment of the present invention.

### DESCRIPTION OF SPECIFIC EMBODIMENTS

Hereinafter, preferred embodiments of the present invention will be described in detail with reference to the accompanying drawings.

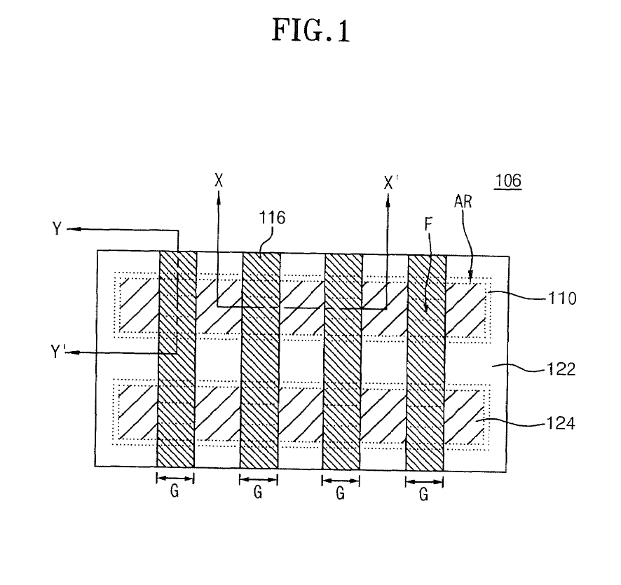

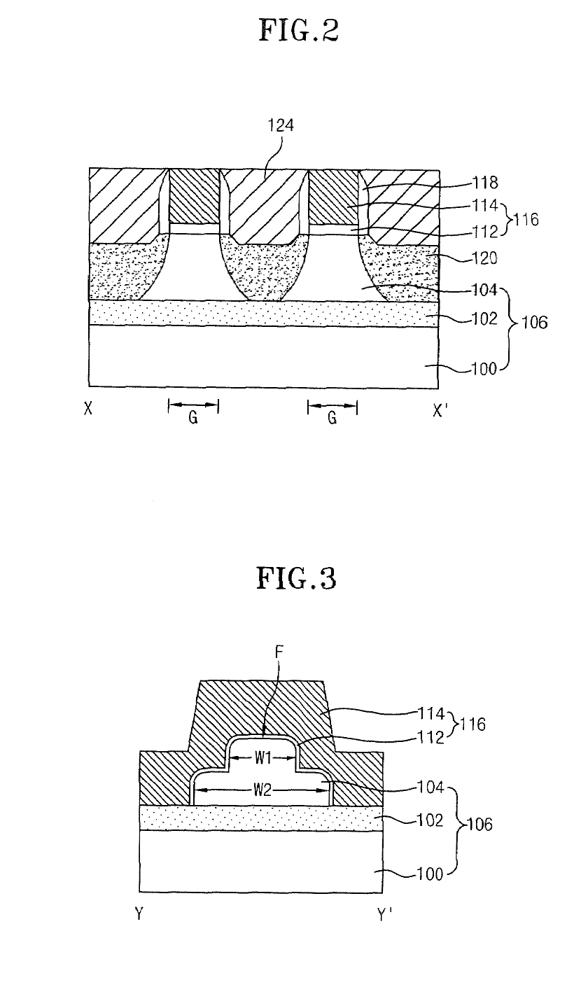

FIG. 1 is a plan view showing a semiconductor device in accordance with an embodiment of the present invention, and FIGS. 2 and 3 are cross-sectional views taken along lines X-X′ and Y-Y′ respectively, and showing the semiconductor device in accordance with an embodiment of the present invention.

Referring to FIGS. 1 through 3, a silicon on insulator (SOI) substrate 106 having a stacked structure of a silicon substrate 100, a filled oxide layer 102, and a silicon layer 104 is prepared. The silicon layer 104 is etched in order to define active regions AR. The active regions AR are each provided with fin patterns F in which both edge portions of a gate forming region G are recessed in the direction of the channel width and the middle portion projects. Referring specifically to FIG. 3, the width of the fin pattern F is wider at the lower end portion than at the upper end portion. Specifically, the fin pattern F has a width W1 in the range of 30-40 nm at the upper end portion, and has a width W2 in the range of 50-70 nm at the lower end portion.

In each of the gate forming regions G of the SOI substrate 106 including the fin patterns F a gate 116 (for example, a gate including a stacked structure of a gate insulation layer 112 and a gate conductive layer 114) is formed. The gates 116 is formed such that they cover the fin patterns F in the active regions AR, and each of the gates has a linear shape extending in a direction perpendicular to the active regions AR on the SOI substrate 106.

Junction region 120 is formed within the active region AR at each side of the gate 116. The junction region 120 is formed so that a lower end portion of the junction region 120 is in contact with the filled oxide layer 102 of the SOI substrate 106 as is shown in FIG. 2. Accordingly, the semiconductor device according to an embodiment of the present invention has a floating body cell structure (hereinafter, referred as a FBC structure) in which the portion of the active region AR between the junction regions 120 is floated. Therefore, the semiconductor device according to an embodiment of the present invention can accumulate holes in the body portion and can read data through the variation in threshold voltage due to the accumulated holes, and thus it does not require a separate capacitor for storing information.

An interlayer dielectric layer 122 is formed over the SOI substrate 106 formed with the gates 116 and the junction regions 120 in order to fill in the space between the gates 116. Contact plugs 124 are formed within the interlayer dielectric layer 122 and each is in contact with the junction region 120.

In FIG. 1, reference numeral 110 denotes a liner insulation layer, and in FIG. 2, reference numeral 118 denotes a gate spacer.

As described above, since the semiconductor device according to an embodiment of the present invention is provided with the fin pattern F having a width that is wider at the lower end portion than the width at the upper end portion in the gate forming region G, it is possible to improve the punch-through at the upper end portion of the fin pattern F (which has a narrow width) while increasing the volume of the body portion at the lower end portion of the fin pattern F (which has a wide width).

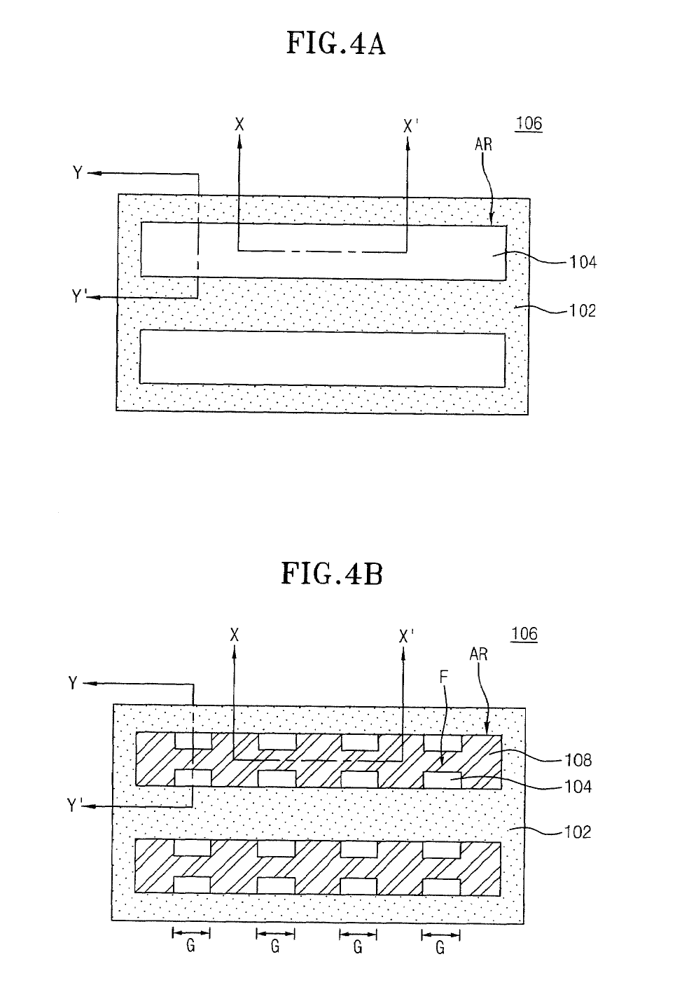

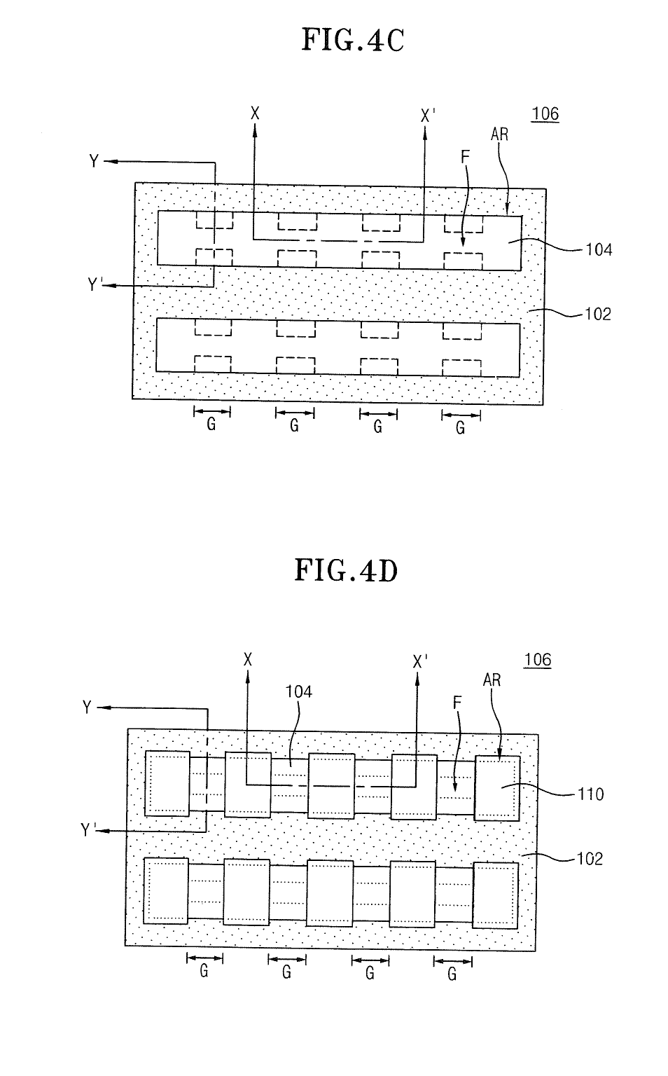

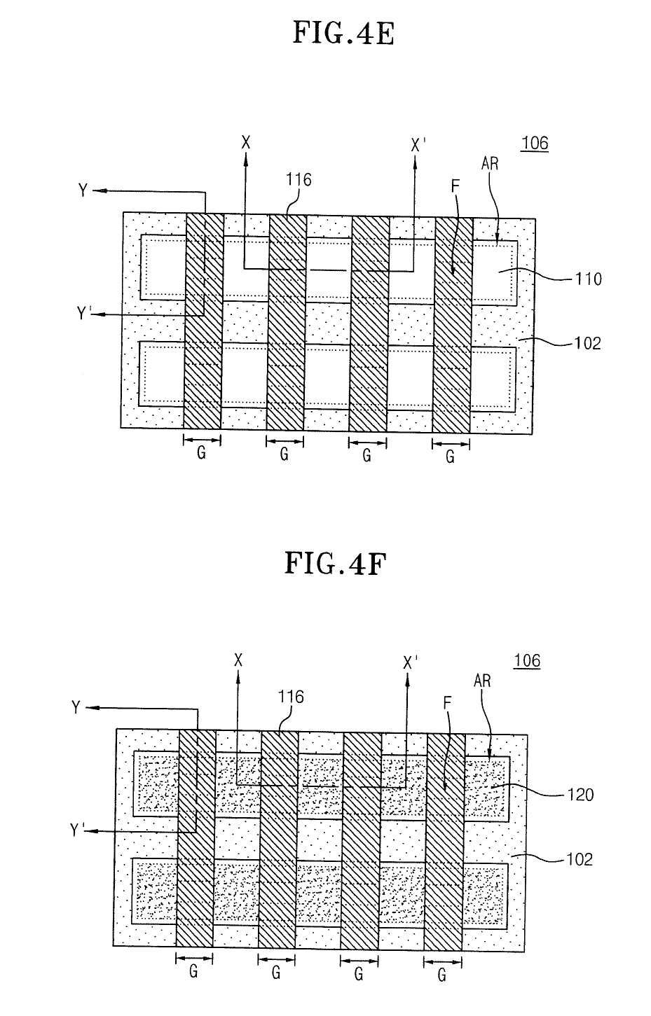

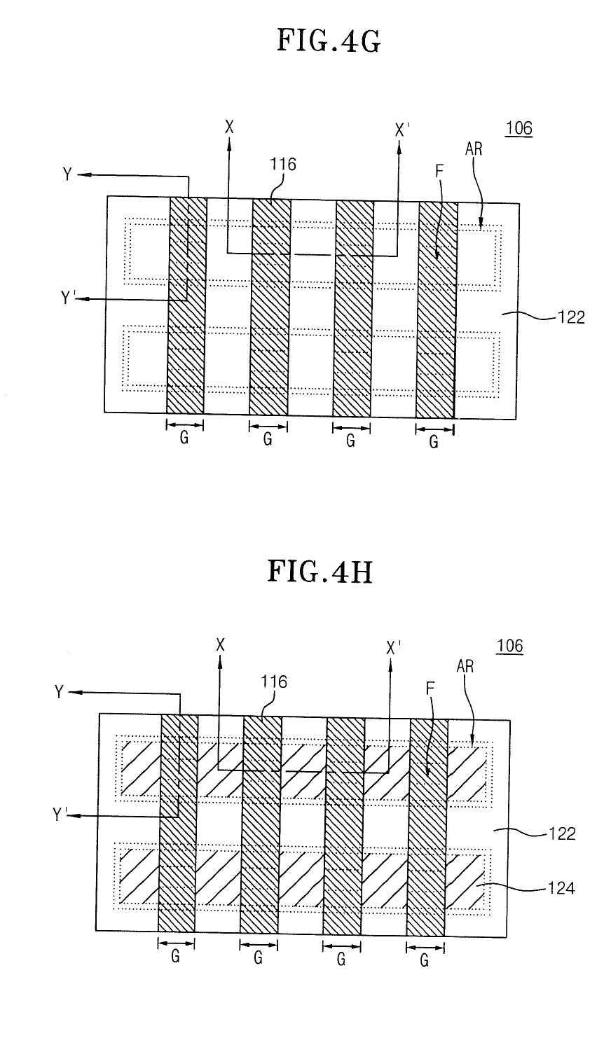

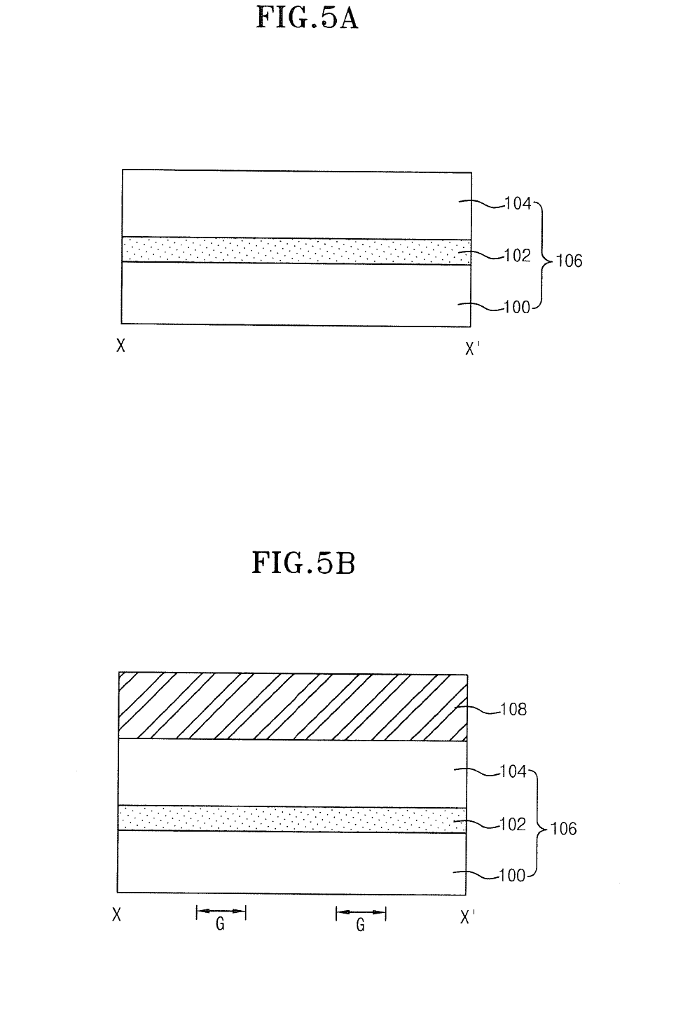

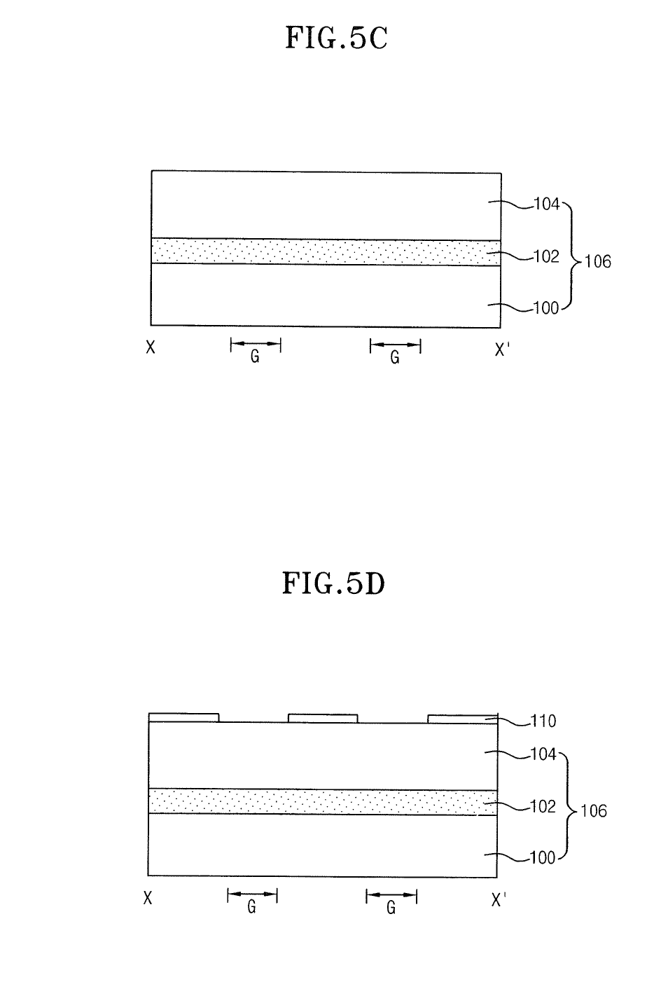

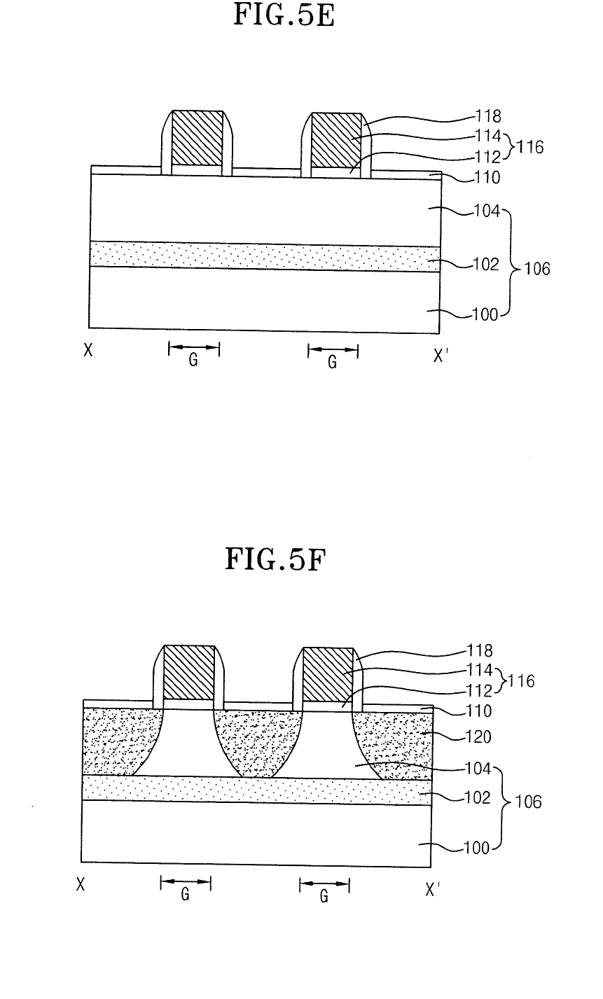

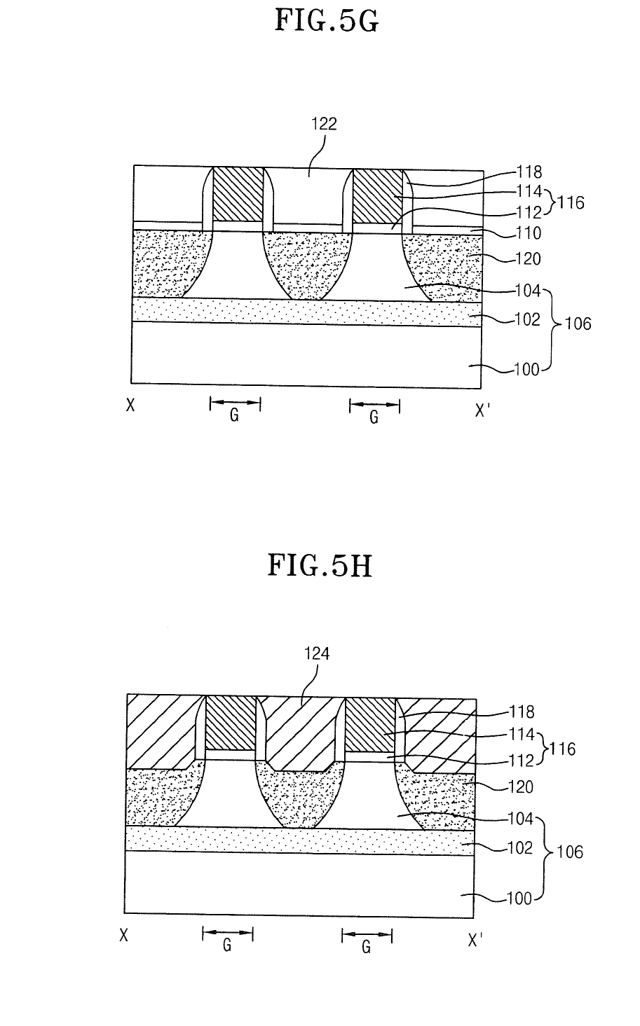

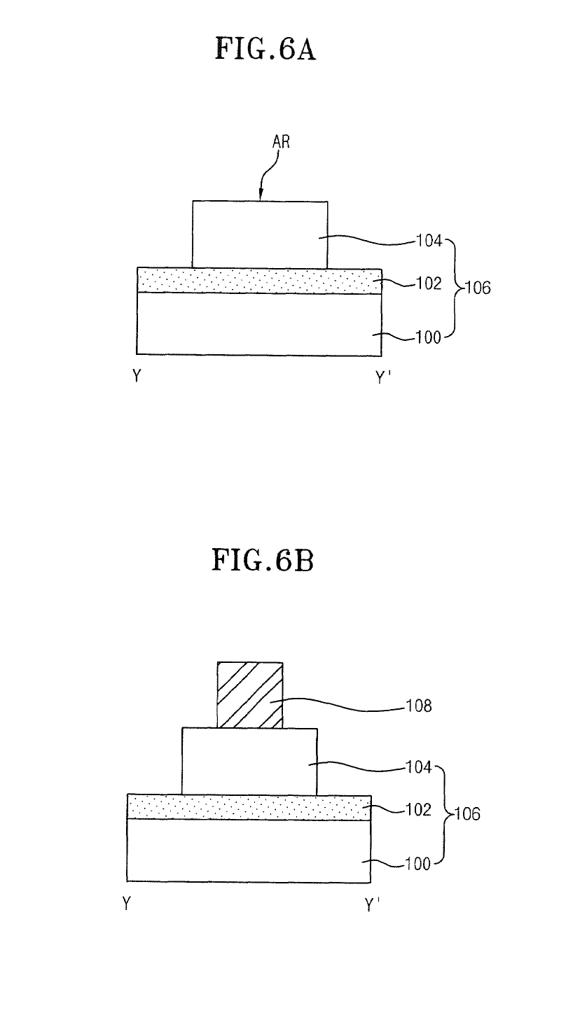

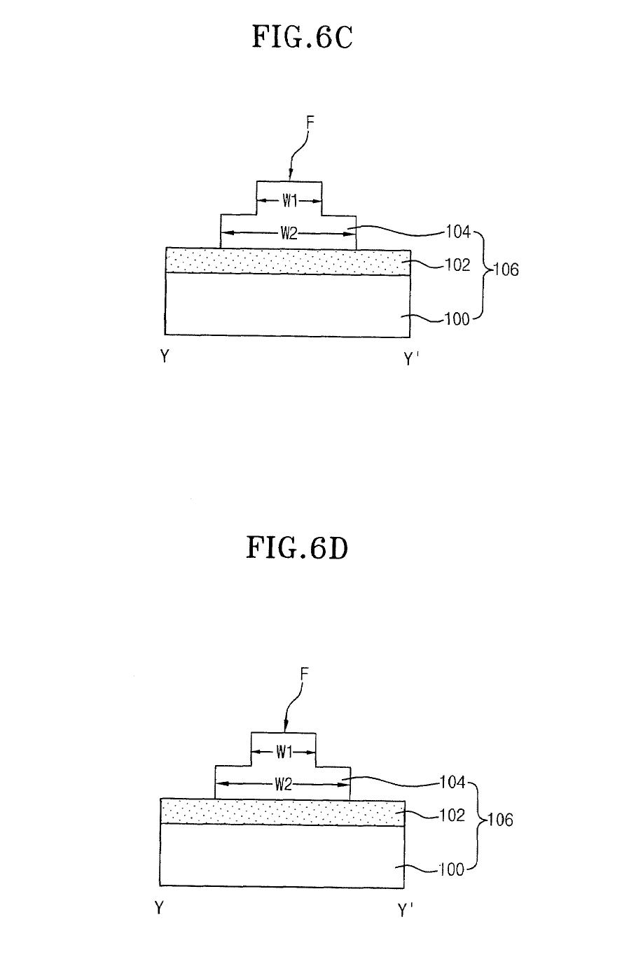

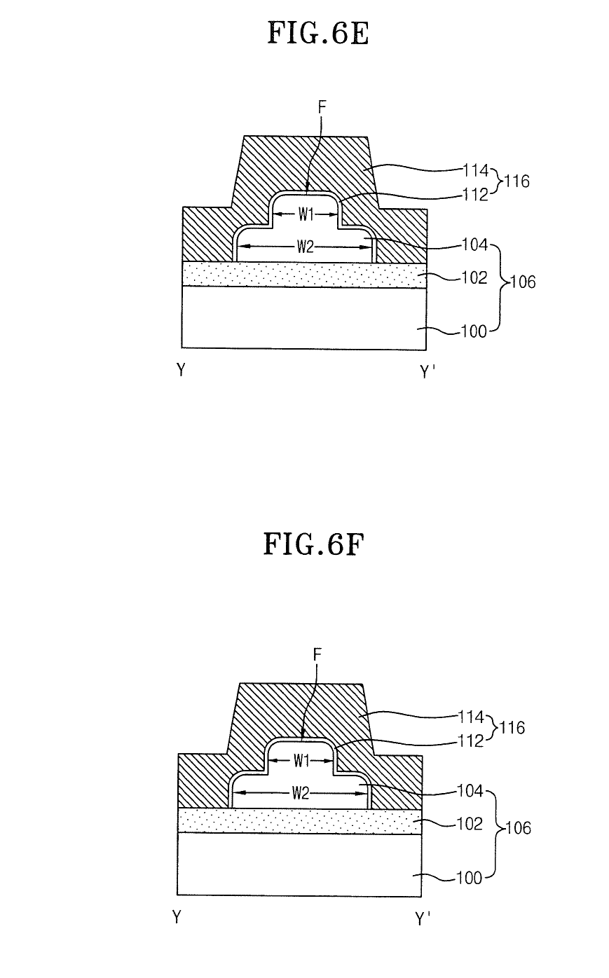

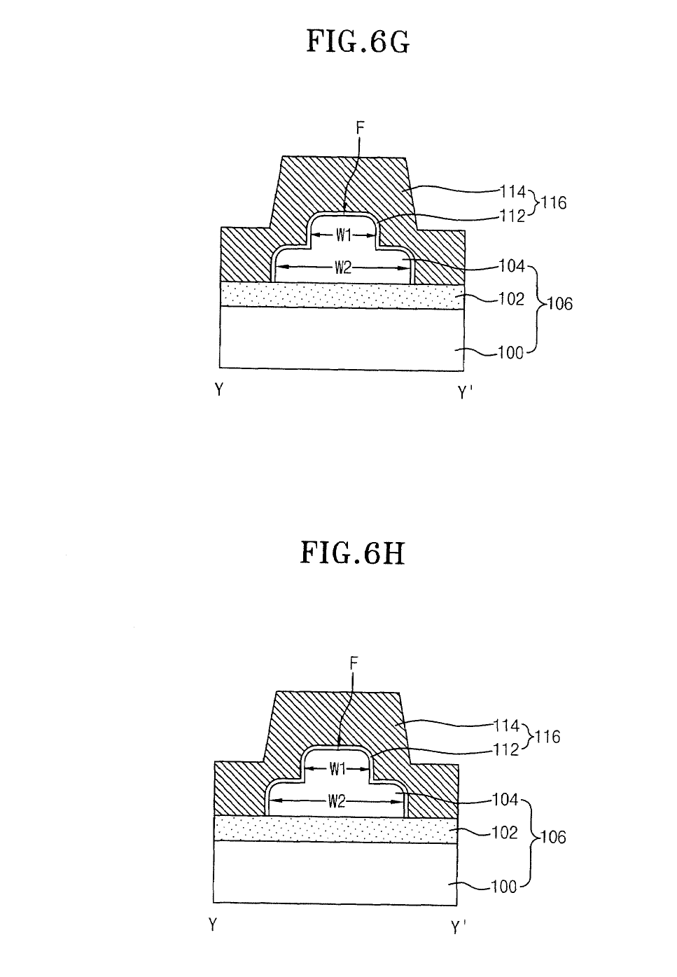

FIGS. 4A through 4H are plan views shown for illustrating the steps in a method for manufacturing a semiconductor device in accordance with an embodiment of the present invention, and FIGS. 5A through 5H and FIGS. 6A through 6H are cross-sectional views taken along lines X-X′ and Y-Y′ respectively of FIGS. 4A through 4H, and are shown for illustrating the steps in a method for manufacturing the semiconductor device in accordance with an embodiment of the present invention.

Referring to FIGS. 4A, 5A, and 6A, active regions AR are defined by etching the silicon layer 104 of the SOI substrate 106 (which has the stacked structure including the silicon substrate 100, the filled oxide layer 102, and the silicon layer 104).

Referring to FIGS. 4B, 5B, and 6B, a mask pattern 108 is formed over the active region AR. The mask pattern 108 exposes some portions of the gate forming regions G; and preferably, both edge portions of each of the gate forming regions G of the active region AR in the direction of channel width are exposed. Though not shown, it is also possible to form the mask pattern 108 over the entire surface of the SOI substrate 106 including the active region AR and the insulation layer 102.

Referring to FIGS. 4C, 5C, and 6C, a thickness (a portion) of the active region AR (preferably a thickness of 300-500Å is recessed using the mask pattern as an etch mask. Thereafter, the mask pattern is removed. As the result, the fin pattern F is formed with a width W2 that is wider at the lower end portion than the width W1 at the upper end portion. As shown in FIG. 4C, the fin pattern F is formed in the gate forming region G of the active region AR. More particularly, the width W1 of the upper end portion of the fin pattern F is in the range of 30-40 nm, and the width W2 of the Is lower end portion is in the range of 50-70 nm.

Referring to FIGS. 4D, 5D, and 6D, the liner insulation layer 110 is formed over the surface of the active region AR formed with the fin patterns F. The liner insulation layer 110 includes, for example, a stacked structure including a silicon oxide (SiO₂) layer and a silicon nitride (SiN) layer. The portions of the liner insulation layer 110 that are formed over the surfaces of the fin patterns F is removed; and as a result, the liner insulation layer 110 no longer remains on the fin patterns F (i.e., the liner insulation layer is only on the portions of the active region AR excluding the fin patterns F).

Referring to FIGS. 4E, 5E and 6E, the gate insulation layer 112 is formed over the surface of the fin patterns F in which the liner insulation layer 110 is removed. The gate insulation layer 112 is formed, for example, as an oxide layer using an oxidation process. At this time, the edge portions of the fin patterns F may be rounded by the oxidation process. Then, a gate conductive layer 114 and a gate hard mask layer (not shown) are sequentially formed over the entire surface of the SOI substrate 106 formed with the gate insulation layer 112. The gate conductive layer 114 includes, for example, a stacked structure of a polysilicon layer and a metallic layer, and the gate hard mask layer includes, for example, a silicon nitride layer.

The gate hard mask layer, the gate conductive layer 114, and the gate insulation layer 112 are etched to form the gates 116 which cover the fin patterns F of the active regions AR. The gates 116 is formed to have a linear shape that extends in a direction perpendicular to the active region AR. Spacers 118 are formed on both side walls of each of the gates 116.

Referring to FIGS. 4F, 5F, and 6F, the junction regions 120 are formed within the active region AR at both sides of each of the gates 116. The junction regions 120 are formed, for example, using an ion implantation process with an N-type impurity (e.g., phosphorous). The ion implantation process is carried out at a dose in the range of 1.0×10¹³ to 1.0×10¹⁴ ions/cm² with energy in the range of 20 to 50 keV. At this time, the concentration of the junction regions 120 is lower as it extends from the surface of the active region AR to the filled insulation layer 102. As a result, the junction regions 120 have a relatively high concentration at the upper end portion of the fin pattern F that has a narrow width, and the junction region 120 has a relatively low concentration at the lower end portion of the fin pattern F that has a wide width.

Herein, the junction regions 120 are formed so that the lower end portion of the junction region 120 is in contact with the filled oxide layer 102 of the SOI substrate 106. Accordingly, the semiconductor device according to an embodiment of the present invention has a FBC structure in which the portion of the active region AR between the junction regions 120 is floated. Therefore, since the semiconductor device according to an embodiment of the present invention can store holes in the floated body portion, the semiconductor device does not require a separate process for forming a capacitor for storing information.

Referring to FIGS. 4G, 5G, and 6G, the interlayer dielectric layer 122 is formed over the resultant SOI substrate formed with the junction region 120 in order to cover the gate 116 and the junction region 120. Then, the interlayer dielectric layer 122 is chemical mechanical polished in order to expose the gate 116. The interlayer dielectric layer 122 serves as an insulation layer between the gates 116 by filling in spaces between the gates 116, and also serves as an isolation layer by filling in spaces between the active regions AR.

Referring to FIGS. 4H, 5H, and 6H, the interlayer dielectric layer 122 is etched to form contact holes for exposing the junction regions 120, and contact plugs 124 are formed within the contract holes to contact the junction region 120. The contact plugs 124 are preferably formed of a polysilicon layer having a concentration in the range of 1.0×10²⁰-2.0×10²⁰ ions/cm³.

The contact hole may be formed such that the interlayer dielectric layer 122 and a portion of the junction region 120 therebelow are both etched. In this case, the contact plug 124 may be formed so that at least one portion thereof is in contact with the upper end portion of the fin pattern F.

Thereafter, though not shown, a series of known follow-up processes is sequentially performed to complete the manufacturing process of the semiconductor device in accordance with an embodiment of the present invention.

As is apparent from the above description, in the present invention, the fin pattern has a wider width at the lower end portion than the width at the upper end portion of the fin by etching both edge portions of the gate forming region of the active region. The gate is formed to cover the fin pattern, and the junction region and the contact plug in contact with the junction region are formed at both sides of the gate. Accordingly, in the present invention, since the body portion surrounded by the junction region and the insulation layer of the SOI substrate is floated and holes can be stored in the floated body portion, it is not necessary to form a capacitor. Therefore, the semiconductor device of the present invention is advantageous when manufacturing a highly integrated device.

Additionally, in the present invention, it is possible to increase the volume of the body at the lower end portion of the fin pattern (which has the wider width), and therefore it is possible to increase the difference in threshold voltage between when the holes are stored in the body and when the holes are flowed out from the body. Therefore, it is possible to effectively enhance the sensing margin.

Further, in the present invention, since the junction region with relatively high concentration is formed at both sides of the upper end portion of the fin pattern having narrow width, it is possible to improve the punch-through phenomenon. Moreover, the punch-through phenomenon can be more improved by forming the contact plug with high concentration, some portion thereof being in contact with the upper end portion of the fin pattern having the narrow width.

Furthermore, in the present invention, it is possible to omit the process of forming an isolation layer by forming an interlayer dielectric layer to fill in the space between the active region and the gates after forming the gate in the gate forming region of the active region. Therefore, it is possible to simplify the manufacturing process of the semiconductor device.

Although specific embodiments of the present invention have been described for illustrative purposes, those skilled in the art will appreciate that various modifications, additions, and substitutions are possible, without departing from the scope and the spirit of the invention as disclosed in the accompanying claims.

What is claimed is:

1. A semiconductor device with a silicon on insulator (SOI) substrate having a stacked structure including a silicon substrate, a filled oxide layer, and a silicon layer and the silicon layer having a gate forming region, the semiconductor device comprising:
a fin pattern formed in the silicon layer at the gate forming region and extending in a channel width direction, wherein the width of a lower end portion of the fin pattern extending in the channel width direction is wider than the width of an upper end portion of the fin pattern extending in the channel width direction;
a gate covering the fin pattern; and
a junction region formed within the silicon layer at each side of the gate.

2. The semiconductor device according to claim 1, wherein the width of the upper in portion is in the range of 30-40 nm and the width of the lower end portion is in the range of 50-70 nm.

3. The semiconductor device according to claim 1, wherein each of the junction regions has a concentration slope in which the concentration is higher at the surface of the silicon layer and is lower at the filled oxide layer.

4. The semiconductor device according to claim 1, further comprising:
an interlayer dielectric layer formed over the SOI substrate formed with the gate and the junction region; and
a contact plug formed within the interlayer dielectric layer so as to be in contact with the junction region.

5. The semiconductor device according to claim 4, wherein the contact plug comprises a polysilicon layer having a concentration in the range of 1.0×10²⁰-2.0×10²⁰ ions/cm³.

6. A method for manufacturing a semiconductor device having an SOI substrate including a stacked structure of a silicon substrate, a filled oxide layer, and a silicon layer and the silicon layer having a gate forming region extending in a channel width direction, the method comprising the steps of:
etching the silicon layer of the SOI substrate to define an active region;
recessing both edge portions of the gate forming region in the active region, the edge portions being opposite each other in the channel width direction, to form a fin pattern such that the width of the fin pattern at a lower end portion of the fin pattern is wider than the width of the fin pattern at an upper end portion of the fin pattern;
forming a gate covering the fin pattern; and
forming a junction region within the active region at each side of the gate.

7. The method according to claim 6, wherein the step of forming the fin pattern comprises the steps of:
forming a mask pattern exposing both of the edge portions of the gate forming region over the active region;
recessing the exposed portion of the active region using the mask pattern as an etching mask; and
removing the mask pattern.

8. The method according to claim 7, wherein the step of recessing the exposed portion of the active region is carried out such that the exposed portion of the active region is removed at a thickness in the range of 300-500Å.

9. The method according to claim 6, wherein the fin pattern is formed such that the width of the upper end portion is in the range of 30-40 nm and the width of the lower end portion is in the range of 50-70 nm.

10. The method according to claim 6, further comprising, after the step of forming the fin pattern and before the step of forming the gate to cover the fin pattern, the step of forming a liner insulation layer over the surface of the active region except for the fin pattern.

11. The method according to claim 6, wherein the junction region is formed by ion implanting N type impurities at a dose in the range of 1.0×10¹³ to 1.0×10¹⁴ ions/cm².

12. The method according to claim 6, wherein the junction region is formed by ion implanting N type impurities at an energy in the range of 20 to 50 keV.

13. The method according to claim 6, wherein each junction region has a concentration slope in which the concentration is higher at the surface of the silicon layer and is lower at the filled oxide layer.

14. The method according to claim 6, further comprising, after the step of forming the junction region, the steps of:
forming an interlayer dielectric layer over the SOI substrate formed with the gate and the junction region to fill in the spaces surrounding the gate;
etching the interlayer dielectric layer to form a contact hole exposing each junction region; and
forming a contact plug in each contact hole such that the contact plug is in contact with the junction region.

15. The method according to claim 6, wherein the contact plug is formed of a polysilicon layer having a concentration in the range of 1.0×10²⁰-2.0×10²⁰ ions/cm³.
